(19) United States
(12) Patent Application Publication
(10) Pub. No.: US 2025/0056875 A1
(43) Pub. Date: Feb. 13, 2025

(54) Efficient FET Body and Substrate Contacts

(71) Applicant: Murata Manufacturing Co., Ltd., Kyoto (JP)

(72) Inventors: Jagar Singh, New York, NY (US); Simon Edward Willard, Irvine, CA (US)

(21) Appl. No.: 18/366,887

(22) Filed: Aug. 8, 2023

(51) Int. Cl. H01L 27/092; H01L 21/8238; H01L 27/12; H01L 29/08; H01L 29/10; H01L 29/66

(52) U.S. Cl. CPC H01L 27/0922; H01L 21/823807; H01L 27/1207; H01L 29/086; H01L 29/0878; H01L 29/1054; H01L 29/66636

(57) ABSTRACT

Integrated circuit structures that significantly reduce the resistance associated with the body contact region and substrate region contact of a field-effect transistor (FET) compared to conventional designs. Embodiments include a FET having a body contact region, and optionally a substrate region contact, that includes germanium (Ge) alone or as an alloy with silicon (SiGe) and/or as a layered combination with silicon (e.g., a layer of Ge on a layer of Si). A first method includes fabricating a body contact region of a field-effect transistor by fabricating the field-effect transistor with an Si body contact region, and diffusing or implanting Ge within the Si. A second method includes fabricating a body contact region of a field-effect transistor by fabricating the field-effect transistor with an Si body contact region, etching away at least part of the Si body contact region to form a well, and depositing Ge within the well.

### BACKGROUND

### (1) Technical Field

This invention relates to electronic integrated circuits, and more particularly to electronic integrated circuits having metal-oxide-semiconductor field-effect transistors (MOSFETs).

### (2) Background

Virtually all modern electronic products—including laptop computers, mobile telephones, and electric cars—utilize metal oxide-semiconductor field-effect transistor (MOSFET) integrated circuits (ICs), and in many cases MOSFET ICs fabricated using a semiconductor-on-insulator (SOI) process, such as silicon-on-insulator, or germanium-on-insulator, or silicon/germanium-on-insulator (e.g., a SiGe alloy or a layer of Ge on a layer of Si formed on an insulator).

SOI technology encompasses the use of a layered silicon-insulator-silicon substrate in place of conventional “bulk” silicon substrates in semiconductor manufacturing. More specifically, SOI transistors are generally fabricated on a layer of silicon dioxide, SiO₂ (often called a “buried oxide” or “BOX” layer) formed on a bulk silicon substrate. The BOX layer reduces certain parasitic effects typical of bulk silicon MOSFET processes, thereby improving performance, particularly for radio frequency (RF) applications. SOI-based devices thus differ from conventional bulk silicon devices in that the silicon regions of the MOSFET transistors are fabricated on an electrical insulator (typically silicon dioxide or aluminum oxide) rather than on a bulk silicon substrate.

FIG. 1A is a stylized cross-sectional view of a typical prior art SOI IC structure 100 for a single MOSFET. The SOI structure 100 includes a substrate 102, a buried-oxide (BOX) insulator layer 104, and an active layer 106 (note that the dimensions for the elements of the SOI IC structure 100 are not to scale; some dimensions have been exaggerated for clarity or emphasis). The substrate 102 is typically a semiconductor material such as silicon. The BOX layer 104 is a dielectric, and is often SiO₂ formed as a “top” surface of the silicon substrate 102, such as by oxidation, layer transfer, or implantation.

The active layer 106 may include some combination of implants and/or layers that include dopants, dielectrics, polysilicon, conductive wiring, passivation, and other materials to form active and/or passive electronic components and/or mechanical structures. For example, FIG. 1A shows a FET comprising a source S, a gate structure G, and a drain D. A conductive source contact 112, a conductive gate contact 114, and a conductive drain contact 116 are respectively formed in contact with the source S, the gate structure G, and the drain D. In the illustrated example, the gate structure G is surrounded by insulating spacers 118.

The illustrated gate structure G includes a conductive layer 108, such as polysilicon, atop an insulating gate oxide (GOX) layer 110. A body B is defined by and below the gate structure G, between the source S and the drain D. In operation, a “conduction channel” (for an enhancement mode FET) or an “inversion channel” (for a depletion mode FET) is generated within the body B between the source S and the drain D and generally proximate to the GOX layer 110 (e.g., within about the top 100 Å of the body B).

If the source S and drain D are highly doped with N type material, the FET is an N-type FET, or NMOS device. Conversely, if the source S and drain D are highly doped with P type material, the FET is a P-type FET, or PMOS device. In either case, the body B will be of an opposite doping polarity. Thus, the source S and drain D doping type determines whether a FET is an N-type or a P-type. Thus, the FET in FIG. 1A is an N-type FET having a P− body B. CMOS devices comprise N-type and P-type FETs co-fabricated on a single IC die. A single IC die may embody from one electronic component—such as a single FET—to many millions of electronic components.

The BOX layer 104 and the active layer 106 (which may include one or more FETs) may be collectively referred to as a “device region” or “substructure” 120 for convenience (noting that other structures or regions may intrude into the substructure 120 in particular IC designs). A superstructure 122 of various elements, regions, and structures may be fabricated in known fashion on or above the substructure 120 in order to implement particular functionality. The superstructure 122 may include, for example, conductive interconnections from the illustrated FET to other components (including other FETs) and/or external contacts, passivation layers and regions, and protective coatings. The conductive interconnections may be, for example, copper or other suitable metal or electrically conductive material. Other elements, regions, and structures may be included for particular circuit designs. The formation of various layers creates a physical coupling between adjacent layers, which may include bonds at the atomic or molecular level and/or merging of layers (e.g., by implantation of dopants or the like). Further, the various elements of the superstructure 122 may extend in three-dimensions and have quite complex shapes. In general, the details of the superstructure 122 will vary from IC design to IC design.

FIG. 1B is a top plan view of the prior art SOI IC structure 100 of FIG. 1A. The cross-section shown in FIG. 1A is along line X-X of FIG. 1B. The source S, gate structure G, and drain D overlay a field of N+ material 124 in this example. The illustrated example shows that the source S is associated with multiple source contacts 112 and the drain D is associated with multiple drain contacts 116, while the gate structure G is shown in this example as only having a single gate contact 114.

Also shown in FIG. 1B is the top side of a body contact region 130 having an associated conductive body contact 132. In the illustrated example, the body contact region 130 comprises a P+ region formed in contact with the P− body B to provide a fourth terminal to the FET.

FIG. 1C is a stylized cross-sectional view of the SOI IC structure of FIG. 1B taken along line Y-Y. Similar in many aspects to the cross-sectional view shown in FIG. 1A, the view in FIG. 1B includes the body contact region 130 and the associated conductive body contact 132 placed to a first side of the gate structure G. Placed to a second side of the gate structure G is a substrate region contact 140 (enclosed by a dashed oval) that includes a conductive substrate contact 142 and a P+ region 144 that penetrates through the active layer 106 to a P region 146 in contact with the substrate 102 (see also top plan view in FIG. 1B). The substrate region contact 140 is isolated from the FET structure by a surrounding region of dielectric 148, such as SiO₂, which may be, for example, a shallow-trench isolation (STI) structure. The substrate region contact 140 provides a fifth terminal to the FET.

FIG. 1D is a schematic diagram of an equivalent circuit for the FET shown in FIGS. 1A-1C. The body B of the FET is essentially coupled to the gate through an equivalent capacitor C_{G}, to the substrate through an equivalent capacitor C_{S}, to the source through an equivalent diode D_{S}, and to the drain through an equivalent diode D_{D}. Notably, the body contact region 130 represents an equivalent resistance R coupled to the body B of the FET.

As is known, the body contact 132—and thus the body contact region 130—is commonly coupled to a bias node such as a power supply, to circuit ground, or to the source S (although other connections are possible). Holes from hot-carriers (generated, for example, from the phenomena of impact ionization) within the body B flow through the body contact region 130 to the body contact 132. Hot-carrier injection is a phenomenon in solid-state electronic devices where a charge carrier (electron or hole) gains sufficient kinetic energy to overcome a potential barrier necessary to break an interface state. In the case of N-type FETs, electrons are trapped within the gate oxide, while holes move toward the body or substrate contacts. Accumulation of holes in the body of the FET raises the body potential and increases the drive current, a phenomenon sometimes known as floating body current. To minimize or eliminate this effect, an efficient hole collection contact is required. Accordingly, the body contact region 130 can reduce or eliminate the problems associated with hot carriers.

The body contact region 130 in a FET fabricated on an SOI substrate is of a special importance—the body contact region 130 eliminates or substantially mitigates the floating body current effect; mitigates turn-on of the parasitic bipolar devices inherent in a MOSFET; improves the breakdown voltage of the FET; improves electro-static discharge (ESD) protection for the FET; improves device and circuitry performance and capability, and in particular improves circuit linearity, reliability, and power consumption in analog and digital circuitry, especially for such devices as RF and mmWave switches, low-noise amplifiers (LNAs), and power amplifiers (PAs).

All of these aspects would be improved if the resistance R associated with the body contact region 130 could be reduced compared to conventional designs. Other aspects of MOSFET performance would be improved if the resistance associated with a substrate region contact 140 is reduced. For example, a low resistance for the substrate region contact 140 also improves the back-bias effectiveness and improves the ESD performance of the device and circuits. The present invention provides a solution to these problems.

### SUMMARY

The present invention encompasses IC structures that significantly reduce the resistance associated with the body contact region and the substrate region contact of a FET compared to conventional designs. Embodiments include a FET having a body contact region, and optionally a substrate region contact, that includes germanium (Ge) alone or as an alloy with silicon (SiGe) and/or as a layered combination with silicon (e.g., a layer of Ge on a layer of Si).

A first aspect of the invention is a method that includes fabricating a body contact region of a field-effect transistor by fabricating the field-effect transistor with a silicon body contact region, and diffusing or implanting germanium within the silicon body contact region.

A second aspect of the invention is a method that includes fabricating a body contact region of a field-effect transistor by fabricating the field-effect transistor with a silicon body contact region, etching away at least part of the silicon body contact region to form a well, and depositing SiGe or germanium layers within the well.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a stylized cross-sectional view of a typical prior art SOI IC structure for a single MOSFET.

FIG. 1B is a top plan view of the prior art SOI IC structure of FIG. 1A.

FIG. 1C is a stylized cross-sectional view of the SOI IC structure of FIG. 1B taken along line Y-Y.

FIG. 1D is a schematic diagram of an equivalent circuit for the FET shown in FIGS. 1A-1C.

FIG. 2 is a first stylized cross-sectional view of an SOI FET through a body contact region (shown encircled by dashed lines).

FIG. 3A is a stylized representation of self-accelerated charge flow between a P− Si body B and an abutting P+ Ge or SiGe body contact region.

FIG. 3B is a schematic representation of the conduction bands E_{C} and valance bands E_{V} relative to the Fermi level E_{F} for Ge and Si, at equilibrium.

FIG. 4 is a second stylized cross-sectional view of an SOI FET through a body contact region (shown encircled by dashed lines).

FIG. 5 is a third stylized cross-sectional view of an SOI FET through a body contact region (shown encircled by dashed lines).

FIG. 6 is a fourth stylized cross-sectional view of an SOI FET through a body contact region (shown encircled by dashed lines).

FIG. 7 is a fifth stylized cross-sectional view of an SOI FET through a body contact region (shown encircled by dashed lines).

FIG. 8 is a sixth stylized cross-sectional view of an SOI FET through a body contact region (shown encircled by dashed lines).

FIG. 9 is a top plan view of a FET IC structure in which the gate G has a “T” configuration.

FIG. 10 is a top plan view of a FET IC structure in which the gate G has an “H” configuration.

FIG. 11 is a top plan view of a FET IC structure in which the gate G has a rectangular configuration.

FIG. 12 is a top plan view of a substrate that may be, for example, a printed circuit board or chip module substrate (e.g., a thin-film tile).

Like reference numbers and designations in the various drawings indicate like elements unless the context requires otherwise.

### DETAILED DESCRIPTION

The present invention encompasses IC structures that significantly reduce the resistance associated with the body contact region and substrate region contact of a FET compared to conventional designs. Embodiments include a FET having a body contact region, and optionally a substrate region contact, that includes germanium (Ge) alone or as an alloy with silicon (SiGe) and/or as a layered combination with silicon (e.g., a layer of Ge on a layer of Si).

The following example embodiments are presented in the context of SOI FETs. However, the teachings regarding lower-resistivity body contact regions and substrate region contacts apply as well to bulk Si FETs.

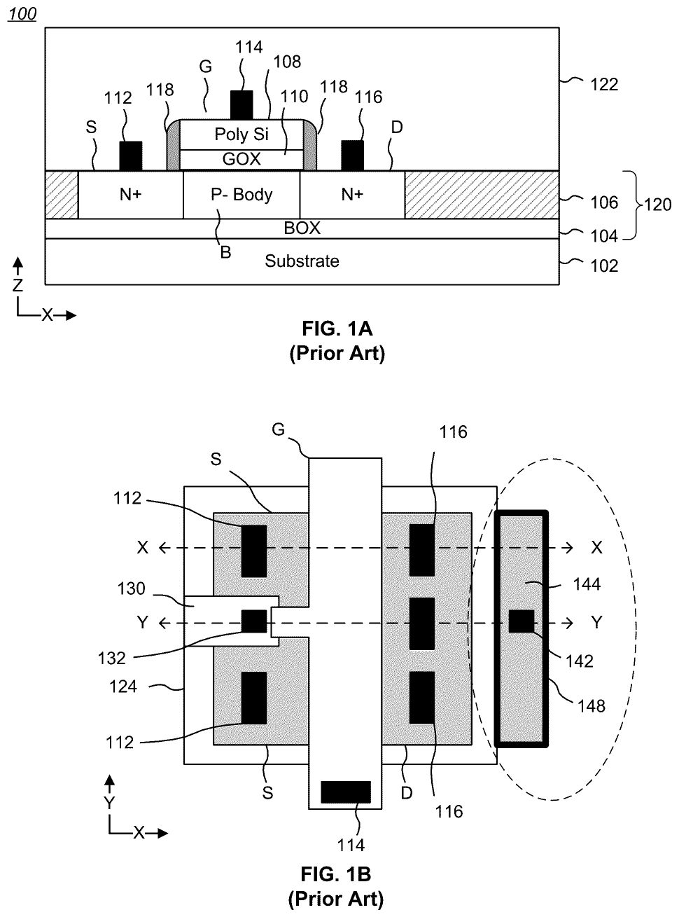

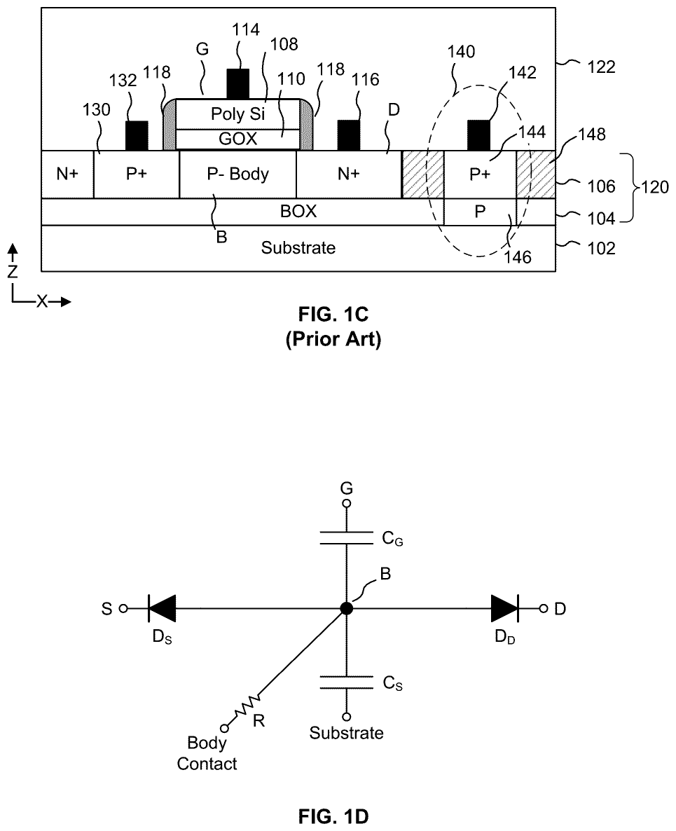

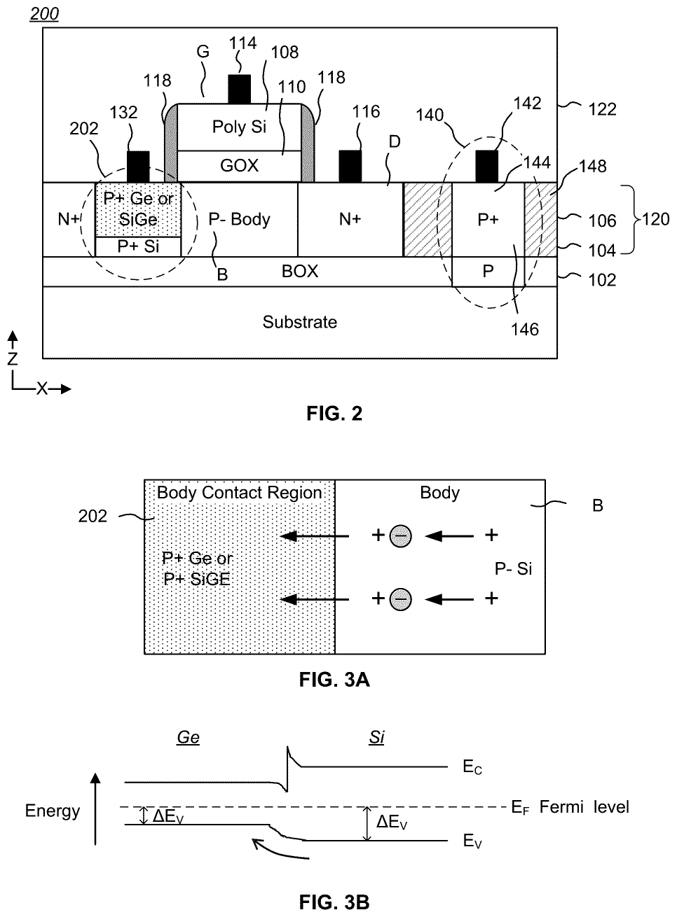

FIG. 2 is a first stylized cross-sectional view of an SOI FET 200 through a body contact region 202 (shown encircled by dashed lines). While the gross structure of the body contact region 202 is similar to the body contact region 130 of FIG. 1C in terms of placement within the overall FET structure, the composition of the body contact region 202 has been altered to significantly reduce the resistance R associated with the body contact region 202.

In the embodiment shown in FIG. 2, the body contact region 202 has been formed of P+ doped Ge or P+ doped SiGe instead of conventional P+ doped Si. In the illustrated example, there is a residual layer of P+ Si at the bottom of the well in which the body contact region 202 is formed, which may result from the particular method selected for creating the Ge/SiGe body contact region 202. The residual layer of P+ Si can act as a seeding layer for a latter step of SiGe or Ge layer formation, such as by epitaxial growth.

A first method of making a SiGe body contact region 202 is to fabricate the FET with a conventional Si body contact region 202, and then diffuse or implant Ge within the Si. A P+ dopant (e.g., boron (B) or boron difluoride (BF₂)) may then be diffused or implanted into the alloyed SiGe. As should be appreciated, the concentration of Ge at the upper layers of the body contact region 202 will approach (and may reach) 100%.

A second method of making a SiGe body contact region 202 is to fabricate the FET with a conventional Si body contact region 202. The Si body contact region 202 may be masked and then etched (at least in part) to form an empty well or void, followed by concurrent deposition of Si and Ge within the well, such as by epitaxial growth. A P+ dopant may then be diffused or implanted into the SiGe. The etching process need not remove all of the original Si from the well, and thus a possibility exists that a layer of Si may remain at the bottom of the well. Accordingly, the body contact region 202 may comprise a layer of P+ doped SiGe on a layer of P+ doped Si.

In terms of overall concentrations, Ge may comprise, for example, from about 1% to about 45% of the total material in the body contact region 202 when using implantation or diffusion of Ge into Si, and from about 15% to about 45% of the total material in the body contact region 202 when using epitaxial deposition or the like of Ge on Si. When layering Ge on Si, an annealing step may be included to diffuse the Ge into the underlying Si, thus forming a SiGe alloy at the layer interface.

A method of making a Ge body contact region 202 is to fabricate the FET with a conventional Si body contact region 202. The Si body contact region 202 may be masked and then etched (at least in part) to form an empty well or void, followed by deposition of Ge within the well. A P+ dopant may then be diffused or implanted into the Ge. It is preferred that a Ge body contact region 202 be monocrystalline for better reduced electrical resistivity, but some applications may use polycrystalline Ge. The etching process need not remove all of the original Si from the well, and thus a possibility exists that a layer of Si may remain at the bottom of the well. Accordingly, in some embodiments, the body contact region 202 may comprise a layer of P+ doped Ge on a layer of P+ doped Si.

In a variation, a layer of Si may be left after the step of etching and then diffused or implanted with Ge to convert that layer to SiGe, after which Ge is deposited to fill the well. A dopant may then be implanted or diffused to convert both the Ge and the SiGe to P+ types. In another variation, a leftover layer of unetched Si may be doped to a P+ type before Ge is diffused or implanted, after which Ge is deposited to fill the well. A dopant may then be implanted or diffused to convert the Ge to a P+ type. In embodiments in which P+ Si is left after the step of etching and a layer of Ge is deposited, to make a better electrical contact, a process like high-temperature treatment (sometimes also called condensation or annealing) may be used. In this process, Ge can diffuse into the underlying Si, thus forming a SiGe alloy.

The importance of Ge, alone or in the alloy SiGe, is that it provides much improved self-acceleration compared to Si alone. For example, FIG. 3A is a stylized representation of self-accelerated charge flow between a P− Si body B and an abutting P+ Ge body contact region 202. Holes (denoted as “+” symbols) will flow from the body B to the Ge body contact region 202, leaving immobile ions behind (denoted as encircled “−” symbols). These ions attract more holes within the body B, which lead to self-acceleration to and charge collection within the Ge body contact region 202. A similar phenomenon occurs when the body contact region 202 comprises SiGe.

The concept shown in FIG. 3A can be further understood by considering the bandgaps of Ge and Si. FIG. 3B is a schematic representation of the conduction bands E_{C} and valance bands E_{V} relative to the Fermi level E_{F} for Ge and Si, at equilibrium. The smaller ΔE_{V} between E_{V} and E_{F} for Ge compared to Si means shows that there would be a free movement of holes from Si to Ge; the same would be true (to a lesser degree) for SiGe instead of Ge. The result is that for both Ge and SiGe, there is a lower hole barrier in the body contact region. In addition, Ge and SiGe provide improved ohmic contact compared Si. For example, P+ Ge has up to about 2 orders of magnitude lower resistivity than P+ Si at temperatures at or below about 400° C.

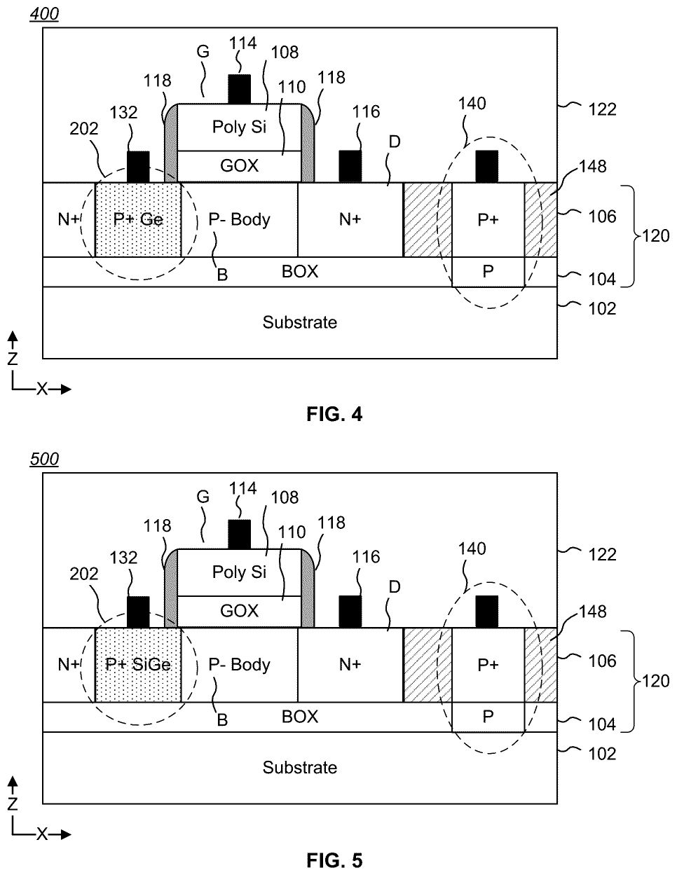

FIG. 4 is a second stylized cross-sectional view of an SOI FET 400 through a body contact region 202 (shown encircled by dashed lines). In the embodiment shown in FIG. 4, the body contact region 202 has been formed of P+ doped Ge instead of conventional P+ doped Si. This variant of the structure shown in FIG. 2 may be made by fabricating the FET with a conventional Si body contact region 202. The Si body contact region 202 may be masked and then etched all the way to the BOX layer 102 to form an empty well or void, followed by deposition of Ge within the well and P+ doping of the Ge. Again, it is preferred that a Ge body contact region 202 be monocrystalline, but some applications may use polycrystalline Ge.

FIG. 5 is a third stylized cross-sectional view of an SOI FET 500 through a body contact region 202 (shown encircled by dashed lines). In the embodiment shown in FIG. 5, the body contact region 202 has been formed of P+ doped SiGe instead of conventional P+ doped Si. This variant of the structure shown in FIG. 2 may be made by fabricating the FET with a conventional Si body contact region 202, and then diffusing or implanting Ge within the Si at an overall concentration as described above. As should be appreciated, the concentration of Ge at the upper layers of the body contact region 202 may approach (and may reach) 100%.

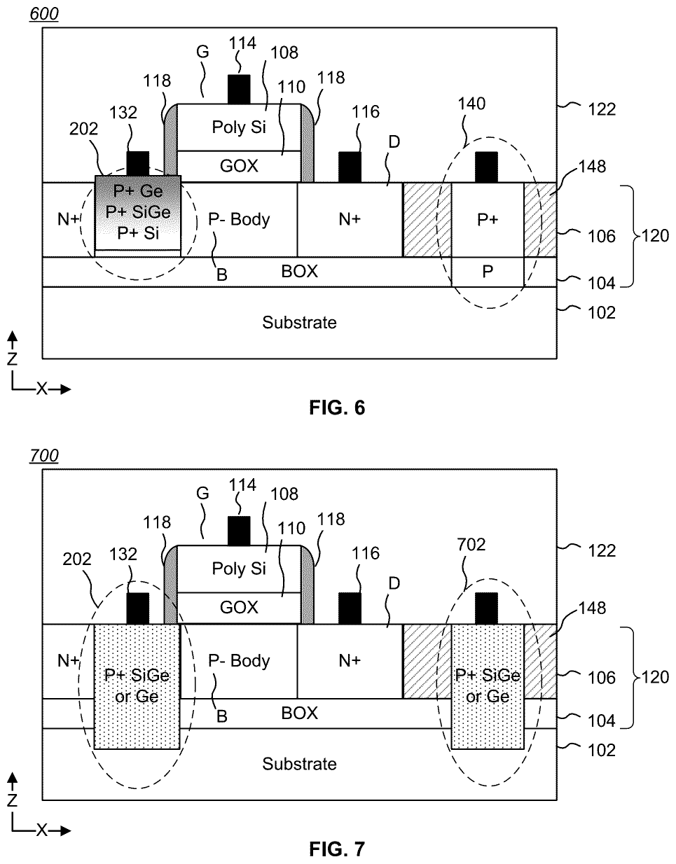

FIG. 6 is a fourth stylized cross-sectional view of an SOI FET 600 through a body contact region 202 (shown encircled by dashed lines). The body contact region 202 is shown in gradient shading to indicate how diffusion or implantation of Ge into an initial Si body contact region 202 results in a mostly P+ Si region near the bottom (relative to the drawing page) of the body contact region 202, a mixed P+ SiGe region in an adjacent middle region, and a mostly P+ Ge region in an adjacent top region of the body contact region 202. As should be appreciated, the mentioned regions do not have abrupt inter-region boundaries but instead generally exhibit a relatively smooth gradation of concentrations of Ge.

FIG. 7 is a fifth stylized cross-sectional view of an SOI FET 700 through a body contact region 202 (shown encircled by dashed lines). The body contact region 202 is shown as being either P+ Ge or SiGe extending through the BOX layer 102 to or into the substrate 102. The associated body contact 132 generally would be coupled to the source S or to a reference potential, such as circuit ground. Connecting the body B to the substrate 102 allows the substrate 102 to serve as a sink for holes generated in the body B, which is particularly beneficial for improving ESD protection.

FIG. 7 also shows that, in addition to or in place of the body contact region 202 extending through the BOX layer 102 to or into the substrate 102, a substrate region contact 702 (enclosed by a dashed oval) may be fabricated using one of the disclosed methods to form a P+ SiGe or Ge structure extending through the BOX layer 102 to or into the substrate 102. As with the body contact region 202, the substrate region contact 702 may comprise a mixture of Si and Ge, with a gradient resulting in a mostly P+ Si region near the bottom (relative to the drawing page) of the substrate region contact 702, a mixed P+ SiGe region in an adjacent middle region, and a mostly P+ Ge region in an adjacent top region of the substrate region contact 702. Again, the mentioned regions do not have abrupt inter-region boundaries but instead generally exhibit a relatively smooth gradation of concentrations of Ge. In terms of overall concentrations, Ge may comprise, for example, from about 1% to about 45% of the total material in the substrate region contact 702 when using implantation or diffusion of Ge into Si; as should be appreciated, the concentration of Ge at the upper layers of the substrate region contact 702 will approach (and may reach) 100% when using implantation or diffusion processes. Ge may comprise, for example, from about 15% to about 45% of the total material in the substrate region contact 702 when using epitaxial deposition or the like of Ge on Si. When layering Ge on Si, an annealing step may be included to diffuse the Ge into the underlying Si, thus forming a SiGe alloy at the layer interface.

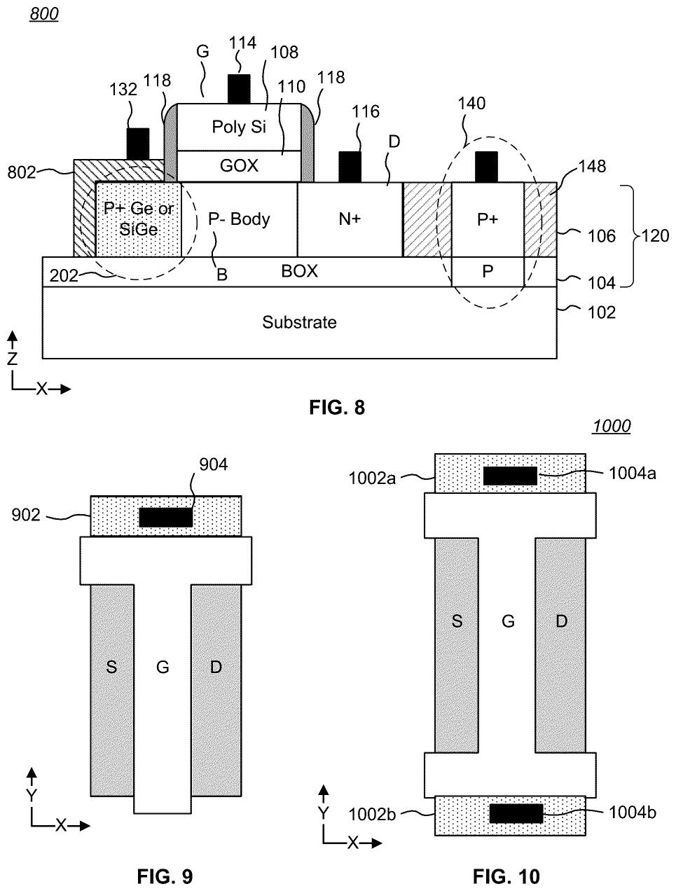

FIG. 8 is a sixth stylized cross-sectional view of an SOI FET 800 through a body contact region 202 (shown encircled by dashed lines). The body contact region 202 is shown as being either P+ Ge or SiGE and capped with a salicide layer 802 (e.g., a transition metal such as titanium, cobalt, nickel, platinum, or tungsten) to further improve the ohmic contact between the body contact region 202 and the body contact 132. In some embodiments, the substrate region contact 702 also may be capped with a salicide layer.

The examples shown in FIGS. 2 and 4-8 have been presented in the context of the plan view of a FET of the type shown in FIG. 1B, in which the body contact region 202 is located along one side (relative to the drawing page) of the gate structure G. However, a FET may have a different configuration for the body contact region (or regions) with respect to the gate structure G.

For example, FIG. 9 is a top plan view of a FET IC structure 900 in which the gate structure G has a “T” configuration. Contacts to the source S and drain D have been omitted to reduce clutter. A body contact region 902 of one of the novel types disclosed above and an associated body contact 904 may be placed at the top (relative to the drawing page) of the “T” of the gate structure G.

As another example, FIG. 10 is a top plan view of a FET IC structure 1000 in which the gate structure G has an “H” configuration. Again, contacts to the source S and drain D have been omitted to reduce clutter. Dual body contact regions 1002a, 1002b of one of the novel types disclosed above and associated body contacts 1004a. 1004b may be respectively placed at the top and bottom (relative to the drawing page) of the “H” of the gate structure G.

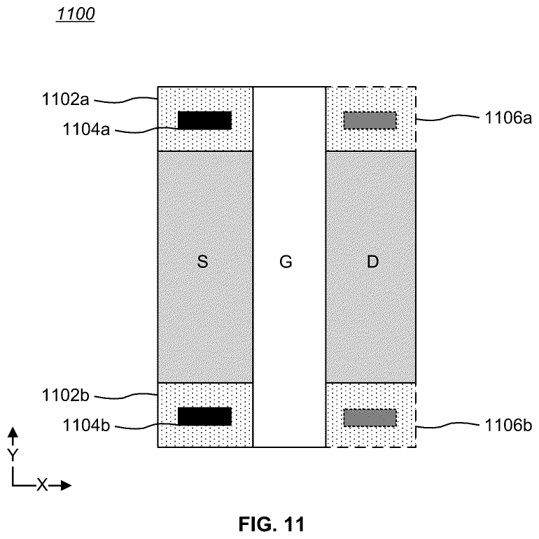

As yet another example, FIG. 11 is a top plan view of a FET IC structure 1100 in which the gate structure G has a rectangular configuration. Again, contacts to the source S and drain D have been omitted to reduce clutter. Dual body contact regions 1102a. 1102b of one of the novel types disclosed above and associated body contacts 1104a, 1104b may be respectively placed along a side of the gate structure G near the top and bottom of the gate structure G and outside of the region defining the source S (compare FIG. 1B, in which the body contact region 130 is embedded within the region defining the source S). Alternatively, the dual body contact regions 1102a, 1102b and associated body contacts 1104a, 1104b may be placed along a side of the gate structure G near the top and bottom of the gate structure G and outside of the region defining the source D (within dashed outlines 1106a, 1106b).

As another alternative, a first body contact region 1102a and associated body contact 1104a may be placed along a side of the gate structure G near the top and outside of the region defining the source S, and a second body contact region 1102b and associated body contact 1104b may be diagonally opposed along a side of the gate structure G near the bottom and outside of the region defining the source D (within dashed outline 1106b).

As yet another alternative, a first set of dual body contact regions 1102a, 1102b of one of the novel types disclosed above and associated body contacts 1104a, 1104b may be respectively placed along a side of the gate structure G near the top and bottom of the gate structure G and outside of the region defining the source S, and a second set of dual body contact regions of one of the novel types disclosed above and associated body contacts may be respectively placed along a side of the gate structure G near the top and bottom of the gate structure G (within dashed outlines 1106a, 1106b) and outside of the region defining the source D.

Additional locations and/or combinations of locations for body contact regions in accordance with the present invention may be selected for particular applications.

It should be appreciated that a low-resistivity Ge and/or SiGe body contact region 202 in accordance with the present invention eliminates or substantially mitigates the floating body effect; mitigates turn-on of the parasitic bipolar devices inherent in a MOSFET; improves the breakdown voltage of the FET; improves electro-static discharge (ESD) protection for the FET; significantly improves device and circuitry performance and capability, and in particular significantly improves circuit linearity, reliability, and power consumption in analog and digital circuitry, especially for such devices as RF and mmWave switches, LNAs, and PAs.

Circuits and devices in accordance with the present invention may be used alone or in combination with other components, circuits, and devices. Embodiments of the present invention may be fabricated as multi-component integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

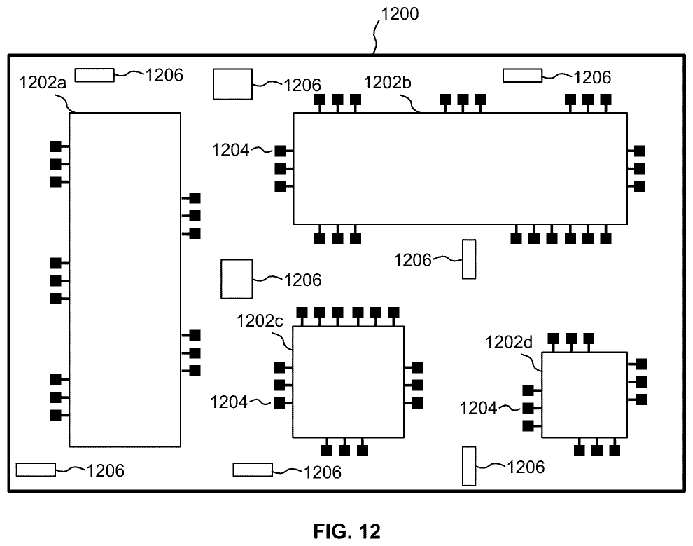

As one example of further integration of embodiments of the present invention with other components, FIG. 12 is a top plan view of a substrate 1200 that may be, for example, a printed circuit board or chip module substrate (e.g., a thin-film tile). In the illustrated example, the substrate 1200 includes multiple ICs 1202a-1202d having terminal pads 1204 which would be interconnected by conductive vias and/or traces on and/or within the substrate 1200 or on the opposite (back) surface of the substrate 1200 (to avoid clutter, the surface conductive traces are not shown and not all terminal pads are labelled). The ICs 1202a-1202d may embody, for example, signal switches, active and/or passive filters, amplifiers (including one or more LNAs), and other circuitry. For example, IC 1202b may incorporate one or more instances of an IC that include FETs having body contact regions 202 and/or substrate region contacts 702 in accordance with the teachings of this disclosure.

The substrate 1200 may also include one or more passive devices 1206 embedded in, formed on, and/or affixed to the substrate 1200. While shown as generic rectangles, the passive devices 1206 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 1200 to other passive devices 1206 and/or the individual ICs 1202a-1202d. The front or back surface of the substrate 1200 may be used as a location for the formation of other structures.

Embodiments of the present invention are useful in a wide variety of radio frequency (RF) circuits and systems for performing a range of functions, including (but not limited to) impedance matching circuits, RF PAS, RF LNAs, phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as BiCMOS, LDMOS, BCD, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A field-effect transistor including a body contact region that includes germanium.

2. The field-effect transistor of claim 1, wherein the body contact region includes a mixture of germanium and silicon.

3. The field-effect transistor of claim 1, wherein the body contact region includes a mixture of germanium and silicon having a gradient of mostly silicon in a first region, a mixture of silicon and germanium in a second region adjacent to the first region, and mostly germanium in a third region adjacent to the second region.

4. The field-effect transistor of claim 1, wherein the body contact region is created by implantation or diffusion of germanium into silicon.

5. The field-effect transistor of claim 1, wherein the body contact region is created by deposition of germanium into an etched well.

6. The field-effect transistor of claim 1, wherein the body contact region includes a mixture of between about 1% germanium and about 100% germanium.

7. The field-effect transistor of claim 1, wherein the body contact region includes an overall concentration of germanium between about 15% and about 45% of the total material in the body contact region.

8. The field-effect transistor of claim 1, wherein the body contact region is in electrical contact with a body region of the field-effect transistor.

9. The field-effect transistor of claim 1, wherein the body contact region is in electrical contact with a body region and a substrate of the field-effect transistor.

10. The field-effect transistor of claim 1, wherein the body contact region is doped with P+ material.

11. The field-effect transistor of claim 1, wherein the body contact region is capped with a salicide layer.

12. A field-effect transistor including a body contact region that includes germanium or a silicon-germanium alloy.

13. The field-effect transistor of claim 12, wherein the body contact region includes an alloy of germanium and silicon having a gradient of mostly silicon in a first region, a mixture of silicon and germanium in a second region adjacent to the first region, and mostly germanium in a third region adjacent to the second region.

14. The field-effect transistor of claim 12, wherein the body contact region is created by implantation or diffusion of germanium into silicon.

15. The field-effect transistor of claim 12, wherein the body contact region is created by deposition of germanium into an etched well.

16. The field-effect transistor of claim 12, wherein the body contact region includes a mixture of between about 1% germanium and about 100% germanium.

17. The field-effect transistor of claim 12, wherein the body contact region includes an overall concentration of germanium between about 15% and about 45% of the total material in the body contact region.

18. The field-effect transistor of claim 12, wherein the body contact region is in electrical contact with a body region of the field-effect transistor.

19. The field-effect transistor of claim 12, wherein the body contact region is in electrical contact with a body region and a substrate of the field-effect transistor.

20. The field-effect transistor of claim 12, wherein the body contact region is doped with P+ material.

21.-72. (canceled)
